(19) United States
(12) Patent Application Publication
(10) Pub. No.: US 2026/0165001 A1
(43) Pub. Date: Jun. 11, 2026

(54) DISPLAY DEVICE, ELECTRONIC DEVICE INCLUDING THE SAME AND METHOD OF FABRICATING THE DISPLAY DEVICE

(71) Applicant: Samsung Display Co., LTD., Yongin-si (KR)

(72) Inventors: Woo Suk JUNG, Yongin-si (KR); Jong Woo KIM, Yongin-si (KR); So Young OH, Yongin-si (KR); Hyun Sup YOON, Yongin-si (KR); Seul Gee LEE, Yongin-si (KR); Jae Heung HA, Yongin-si (KR)

(21) Appl. No.: 19/178,681

(22) Filed: Apr. 14, 2025

(30) Foreign Application Priority Data
Jul. 19, 2024 (KR) 10-2024-0095492

(51) Int. Cl. H10K 59/80; H10K 59/12; H10K 102/00

(52) U.S. Cl. CPC H10K 59/8731; H10K 59/1201; H10K 2102/351

(57) ABSTRACT

A display device includes an emission material layer disposed on a substrate and including a plurality of light-emitting elements; and an encapsulation layer including a first encapsulation layer disposed on the emission material layer and including an inorganic material, a second encapsulation layer disposed on the first encapsulation layer and including an organic material, and a third encapsulation layer disposed on the second encapsulation layer and including an inorganic material. A total thickness of the encapsulation layer is equal to or less than 10,000 angstroms, and a refractive index of the second encapsulation layer is equal to or greater than 1.80.

This application claims priority to Korean Patent Application No. 10-2024-0095492, filed on Jul. 19, 2024, and all the benefits accruing therefrom under 35 U.S.C. § 119, the content of which in its entirety is herein incorporated by reference.

### BACKGROUND

### 1. Field

The disclosure relates to a display device and a method of fabricating the same.

### 2. Description of the Related Art

Display devices become more and more important as multimedia technology evolves. Accordingly, a variety of display devices such as liquid-crystal display devices (“LCDs”) and organic light-emitting diode display devices (“OLEDs”) are currently being developed.

Among display devices, a self-luminous display device includes a self-luminous element, e.g., an organic light-emitting element. A self-luminous element may include two opposing electrodes and an emissive layer interposed therebetween. For an organic light-emitting element as a self-luminous element, electrons and holes supplied from the two electrodes are recombined in the emissive layer to generate excitons, the generated excitons relax from the excited state to the ground state and accordingly light may be emitted.

A separate light source such as backlight unit is not desired in such a self-luminous display device, and thus it consumes less power and may be made relatively light and relatively thin, as well as exhibiting high-quality characteristics such as relatively wide viewing angle, relatively high luminance and contrast, and relatively fast response speed. Accordingly, organic light-emitting display devices are attracting attention as the next generation display device.

### SUMMARY

Features of the disclosure provide a display device including an encapsulation layer having a relatively small thickness and relatively high barrier properties. Features of the disclosure also provide a method of fabricating a display device including an encapsulation layer that may be easily formed.

It should be noted that features of the disclosure are not limited to the above-mentioned feature; and other features of the disclosure will be apparent to those skilled in the art from the following descriptions.

The details of embodiments of the subject matter described in this specification are set forth in the accompanying drawings and the description below.

In an embodiment of the disclosure, a display device includes an emission material layer disposed on a substrate and including a plurality of light-emitting elements; and an encapsulation layer including a first encapsulation layer disposed on the emission material layer and including an inorganic material, a second encapsulation layer disposed on the first encapsulation layer and including an organic material, and a third encapsulation layer disposed on the second encapsulation layer and including an inorganic material. A total thickness of the encapsulation layer is equal to or less than 10,000 angstroms, and a refractive index of the second encapsulation layer is equal to or greater than 1.80.

In an embodiment, the second encapsulation layer may include silazane.

In an embodiment, a water vapor transmission rate (“WVTR”) of the second encapsulation layer may be equal to or less than 1×10-3 gram per square meter per day (g/m2day).

In an embodiment, a transmittance of the second encapsulation layer in a visible range may be equal to or greater than 98%.

In an embodiment, a thickness of the second encapsulation layer may range from 1,000 angstroms to 4,000 angstroms.

In an embodiment, a difference between a refractive index of the first encapsulation layer and the refractive index of the second encapsulation layer and a difference between a refractive index of the third encapsulation layer and the refractive index of the second encapsulation layer may be equal to or less than 0.1.

In an embodiment, the refractive index of the first encapsulation layer and the refractive index of the third encapsulation layer may be greater than the refractive index of the second encapsulation layer.

In an embodiment, the refractive index of the first encapsulation layer and the refractive index of the third encapsulation layer may be equal to or greater than 1.85.

In an embodiment, the first encapsulation layer covers an entirety of the emission material layer, the second encapsulation layer covers an entirety of the first encapsulation layer, and the third encapsulation layer entirely may cover the second encapsulation layer.

In an embodiment, a film density of the first encapsulation layer and a film density of the third encapsulation layer may be equal to or greater than 2.1g/cm3 .

In an embodiment, each of a thickness of the first encapsulation layer and a thickness of the third encapsulation layer may range from 10 angstroms to 100 angstroms.

In an embodiment, a WVTR of the first encapsulation layer and the third encapsulation layer may be equal to or less than 1×10-4 g/m2day.

In an embodiment, the display device may further include a circuit layer disposed between the substrate and the emission material layer. The circuit layer may include a first semiconductor layer, a first insulating layer, a first conductive layer, a second insulating layer, a second conductive layer, a third insulating layer, a second semiconductor layer, a fourth insulating layer, a third conductive layer, a fifth insulating layer and a fourth conductive layer sequentially disposed on the substrate.

In an embodiment of the disclosure, a method of fabricating a display device includes forming an emission material layer including a plurality of light-emitting elements on a substrate; and forming an encapsulation layer on the emission material layer. The forming the encapsulation layer includes: forming a first encapsulation layer; forming a second encapsulation layer on the first encapsulation layer; and forming a third encapsulation layer on the second encapsulation layer. A total thickness of the encapsulation layer is equal to or less than 10,000 angstroms, and the second encapsulation layer includes silazane.

In an embodiment, the second encapsulation layer may have a viscosity of 50 centipoise (cps) or less.

In an embodiment, the forming the second encapsulation layer may include forming the second encapsulation layer using at least one of: inkjet printing, jet dispensing, spin coating, slit coating, and screen printing.

In an embodiment, the forming the second encapsulation layer may include forming the second encapsulation layer by performing thermal curing or ultraviolet (“UV”) curing, and the second encapsulation layer may include silicon nitride after the thermal curing or the UV curing.

In an embodiment, the forming the first encapsulation layer and the third encapsulation layer may include forming the first encapsulation layer and the third encapsulation layer by plasma-enhanced atomic layer deposition (“PEALD”).

In an embodiment, the forming the first encapsulation layer and the third encapsulation layer may include forming the first encapsulation layer and the third encapsulation layer by amino silane precursor.

In an embodiment of the disclosure, an electronic device includes a display device including a substrate; a display device housing in which the display device is accommodated; and an optical member for magnifying a displayed image of the display device or converting a light path. The display device includes: an emission material layer disposed on the substrate and including a plurality of light-emitting elements; and an encapsulation layer including a first encapsulation layer disposed on the emission material layer and including an inorganic material, a second encapsulation layer disposed on the first encapsulation layer and including an organic material, and a third encapsulation layer disposed on the second encapsulation layer and including an inorganic material. A refractive index of the second encapsulation layer is equal to or greater than 1.8, and a WVTR of the second encapsulation layer is equal to or less than 1×10-3 g/m2day.

In an embodiment of the disclosure, a display device may have a relatively small thickness and relatively high barrier properties. In addition, according to the disclosure, a display device may include an encapsulation layer that may be easily produced.

It should be noted that effects of the disclosure are not limited to those described above and other effects of the disclosure will be apparent to those skilled in the art from the following descriptions.

### BRIEF DESCRIPTION OF THE DRAWINGS

The above and other advantages and features of the disclosure will become more apparent by describing in detail embodiments thereof with reference to the attached drawings, in which:

FIG. 1 is a perspective view of an embodiment of a display device according to the disclosure.

FIG. 2 is a plan view showing the display device of FIG. 1.

FIG. 3 is a cross-sectional view taken along line A-A′ of FIG. 2.

FIG. 4 is a cross-sectional view showing an embodiment of a sub-pixel of a display device according to the disclosure.

FIG. 5 is a cross-sectional view showing an embodiment of an encapsulation layer of a display device according to the disclosure.

FIG. 6 shows is a chemical formula of an organic material included in the third encapsulation layer in FIG. 5.

FIG. 7 is a flowchart for illustrating a method of fabricating a display device.

FIG. 8 is a cross-sectional view showing operation S10 of FIG. 7.

FIG. 9 is a cross-sectional view showing operation S20 of FIG. 7.

FIGS. 10 to 11 are cross-sectional views showing operation S30 of FIG. 7.

FIG. 12 shows chemical formulas of the organic material included in the second encapsulation layer before and after curing.

FIG. 13 shows a graph of the transmittance of the second encapsulation layer.

FIG. 14 is a cross-sectional view showing operation S40 of FIG. 7.

FIG. 15 is a perspective view showing a head-mounted display according to the disclosure.

FIG. 16 is an exploded perspective view of an embodiment of the head-mounted display of FIG. 15.

FIG. 17 is a perspective view showing a head-mounted display according to the disclosure.

FIG. 18 is a block diagram of an electronic device according to one embodiment of the present disclosure.

FIG. 19 is a schematic diagram of an electronic device according to various embodiments of the present disclosure.

### DETAILED DESCRIPTION

Embodiments of the disclosure now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it may be directly on the other element or intervening elements may be therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the drawing figures. It will be understood that relative terms are intended to encompass different orientations of the device in addition to the orientation depicted in the drawing figures. For example, if the device in one of the drawing figures is turned over, elements described as being on the “lower” side of other elements would then be oriented on “upper” sides of the other elements. The term “lower,” may therefore, encompasses both an orientation of “lower” and “upper,” depending on the particular orientation of the figure. Similarly, if the device in one of the drawing figures is turned over, elements described as “below” or “beneath” other elements would then be oriented “above” the other elements. The terms “below” or “beneath” can, therefore, encompass both an orientation of above and below.

“About” or “approximately”, if used, may be inclusive of the stated value and means within an acceptable range of deviation for the particular value as determined by one of ordinary skill in the art, considering the measurement in question and the error associated with measurement of the particular quantity (i.e., the limitations of the measurement system). The term such as “about” may mean within one or more standard deviations, or within ±30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the drawing figures are schematic in nature and their shapes are not intended to illustrate the precise shape of a region and are not intended to limit the scope of the claims.

Hereinafter, embodiments of the disclosure will be described in detail with reference to the accompanying drawings.

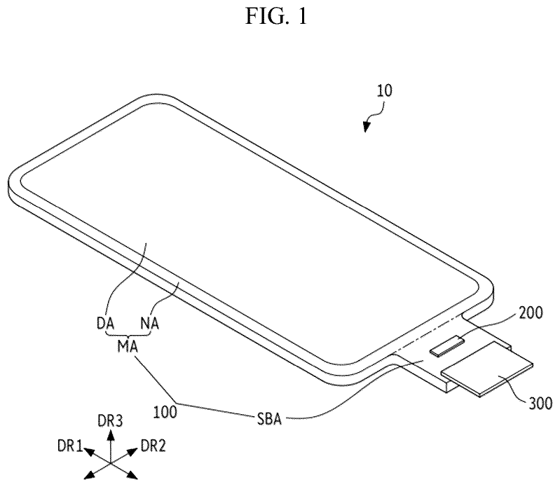

FIG. 1 is a perspective view of an embodiment of a display device according to the disclosure.

Referring to FIG. 1, a display device 10 is for displaying moving images or still images. The display device 1 may be used as the display screen of portable electronic devices such as a mobile phone, a smart phone, a tablet personal computer (“PC”), a smart watch, a watch phone, a mobile communications terminal, an electronic notebook, an electronic book, a portable multimedia player (“PMP”), a navigation device and a ultra mobile PC (“UMPC”), as well as the display screen of various products such as a television, a notebook, a monitor, a billboard and the Internet of Things.

The display device 10 may be a light-emitting display device such as an organic light-emitting display device including organic light-emitting diodes, a quantum-dot light-emitting display device including a quantum-dot emissive layer, an inorganic light-emitting display device including an inorganic semiconductor, and a micro light-emitting display device using micro or nano light-emitting diodes (micro light-emitting diodes (“LEDs”) or nano LEDs). In the following description, an organic light-emitting display device is employed as the display device 10. It is, however, to be understood that the type of the display device 10 is not limited thereto.

In an embodiment, the display device 10 may be flat. In an embodiment, the display device 10 may be substantially flat in the plan view defined by the first direction DR1 and the second direction DR2, and may have a predetermined thickness (or height) in the third direction DR3, for example. In another embodiment of the disclosure, the display device 10 may be curved at at least some portions including the edges. Besides, the display device 10 may be flexible so that it may be curved, bent, folded or rolled.

According to the embodiment of the disclosure, with respect to the image display surface of the display device 10, the first direction DR1 may be the longitudinal direction, the column direction or the vertical direction, and the second direction DR2 may intersect the first direction DR1 and, may be the lateral direction, the row direction or the horizontal direction, for example. The third direction DR3 may be a thickness direction or a height direction of the display device 10.

The display device 10 may include a display panel 100, a driver 200 and a circuit board 300.

The display panel 100 may include a main area MA including a display area DA where images are displayed, and a subsidiary area SBA disposed on one side of the main area MA.

The main area MA may include a display area DA and a non-display area NA surrounding the display area DA. The display area DA may be disposed in the center of the main area MA and may occupy most of the main area MA. The non-display area NA may be disposed at the edges of the main area MA and may contact the subsidiary area SBA.

In the display area DA, the pixels may be arranged and images may be displayed by the pixels. According to the embodiment of the disclosure, the display area DA may further include sensing patterns (e.g., touch electrodes) for sensing a touch input, etc., and the display area DA may include a sensing area that senses a touch input by the sensing patterns.

According to the embodiment, the display area DA may include longer sides in the first direction DR1 and shorter sides in the second direction DR2 and may be formed as a flat surface having a generally quadrangular shape, e.g., rectangular shape. The corners where the longer sides and the shorter sides of the display area DA meet may be rounded or formed at the right angle. The shape of the display area DA may vary depending on embodiments. In an embodiment, the display area DA may be formed in a polygonal shape other than a square shape, a circular shape, or an elliptical shape, for example.

The non-display area NA may be disposed immediately around the display area DA. The non-display area NA may surround the display area DA. Embedded circuitry may be disposed in the non-display area NA. In an embodiment, embedded circuitry including a scan driver circuit or the like may be disposed in the non-display area NA disposed on one side (e.g., the left or right side) or the opposite sides of the display area DA.

The subsidiary area SBA may be disposed on one side of the main area MA. In an embodiment, the subsidiary area SBA may protrude from one side of the main area MA in the first direction DR1, for example. In an embodiment, the subsidiary area SBA may protrude from the lower end of the main area MA in the first direction DR1. According to the embodiment, the subsidiary area SBA may have a smaller width than the main area MA. In an embodiment, the subsidiary area SBA may have a smaller width than the main area ma in the second direction DR2, for example.

Lines and pads may be disposed in the subsidiary area SBA. In an embodiment, in the subsidiary area SBA, the lines and the pads connected to the pixels and/or the embedded circuitry disposed in the main area MA, and the circuit 200 and/or the circuit board 300 disposed in the subsidiary area SBA, for example. In the following description of the embodiments, the term “connection” may encompass electrical connection and/or physical connection.

According to the embodiment, the driver 200 (e.g., a display driver circuit) may be disposed (e.g., mounted) in the subsidiary area SBA. The circuit board 300 may be disposed on a portion of the subsidiary area SBA.

The driver 200 may include a data driver circuit for driving pixels. According to the embodiment, the driver 200 may be formed as an integrated circuit (“IC”) chip and disposed in the subsidiary area SBA. In another embodiment, the driver 200 may be disposed on the circuit board 300 in the subsidiary area SBA, or may be disposed on another circuit board connected to the display panel 100 through the circuit board 300.

The circuit board 300 may be disposed on a portion of the subsidiary area SBA. In an embodiment, the circuit board 300 may be bonded on the pads disposed at a location (e.g., the lower edge) of the subsidiary area SBA, and may supply or transmit supply voltages and driving signals for driving the display panel 100 to the display panel 100, for example. In an embodiment, the circuit board 300 may supply the display panel 100 with input image data (e.g., digital image data), driving signals including timing signals, and driving voltages, for example. The circuit board 300 may be, but is not limited to, a flexible printed circuit board (“FPCB”), a printed circuit board (“PCB”) or a flexible film such as chip on film (“COF”).

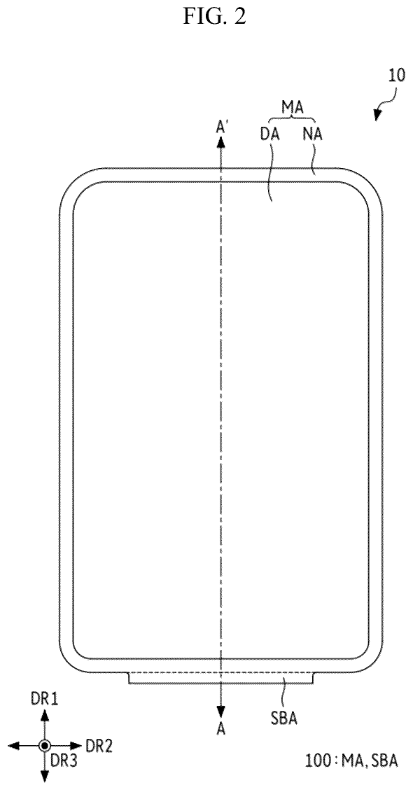

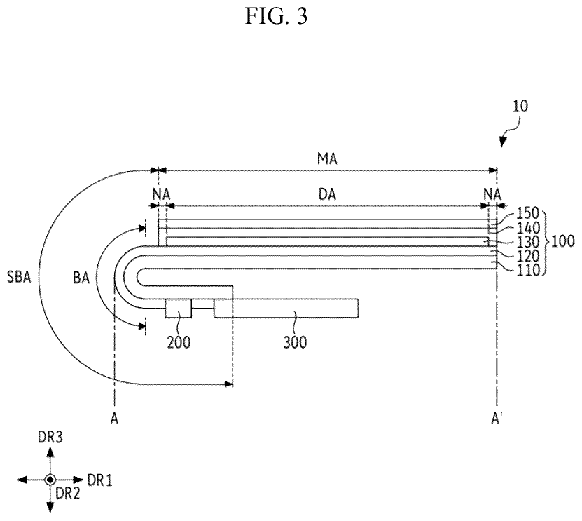

FIG. 2 is a plan view showing the display device of FIG. 1. FIG. 3 is a cross-sectional view taken along line A-A′ of FIG. 2.

FIG. 1 shows an example where the display device 10 is not bent but is unfolded, while FIGS. 2 and 3 show an example where the display device 10 is bent at the subsidiary area SBA. FIG. 1 shows the subsidiary area SBA and the main area MA when they are unfolded, while FIGS. 2 and 3 show the subsidiary area SBA when it is partially bent.

Referring to FIGS. 2 and 3, the display panel 100 may include a substrate 110 including the main area MA and the subsidiary area SBA, and a circuit layer 120, an emission material layer 130, an encapsulation layer 140 and a color filter layer 150 sequentially arranged on the substrate 110. The circuit layer 120 may be disposed in the main area MA as well as the subsidiary area SBA on the substrate 110, and the emission material layer 130, the encapsulation layer 140 and the color filter layer 150 may be disposed partially on the substrate 110 and the circuit layer 120. In an embodiment, the emission material layer 130, the encapsulation layer 140 and the color filter layer 150 may be disposed in the main area MA, for example.

According to the embodiment of the disclosure, the display device 10 may further include additional elements disposed on the display panel 100. In an embodiment, the display device 10 may further include at least one of: a sensor layer (e.g., a touch sensor layer), a polarizing layer and a protective layer (e.g., a window) disposed on the encapsulation layer 140, for example. Each of the sensor layer, the polarizing layer and/or the protective layer may be fabricated integrally with the display panel 100 or separately from the display panel 100 and attached to the display panel 100 via an adhesive layer, etc.

The main area MA may include the display area DA and the non-display area NA. The non-display area NA may be disposed immediately around the display area DA. In an embodiment, the non-display area NA may be the edge area of the main area MA disposed at the border of the display area DA, for example.

The substrate 110 may include an insulating material such as polymer resin. In an embodiment, the substrate 110 may include or consist of polyimide or other insulating materials, for example. The substrate 110 may be a flexible substrate that may be deformed, i.e., bent, folded, or rolled. In an alternative embodiment, the substrate 110 may include or consist of an insulating material such as glass.

The circuit layer 120 may include pixel circuits and lines. In an embodiment, the circuit layer 120 may include circuit elements (e.g., pixel transistors and capacitors) that form the pixel circuits of the pixels, and the lines connected to the pixels, for example. According to the embodiment of the disclosure, the circuit layer 120 may further include circuit elements forming built-in circuits such as a scan driver circuit, and lines connected to the built-in circuits.

The emission material layer 130 may include light-emitting elements arranged in emission areas of the pixels. In an embodiment, each of the pixels may include at least one light-emitting element and a pixel circuit connected to the light-emitting element, for example. The pixels may be disposed in pixel areas, respectively, each of which includes an emission area where a light-emitting element is disposed and a pixel circuit area where a pixel circuit is disposed. The emission area and the pixel circuit area of each pixel may overlap each other, but the disclosure is not limited thereto.

Although the circuit layer 120 and the emission material layer 130 are separated from each other in the embodiments, embodiments of the disclosure are not limited thereto. In an embodiment, the circuit layer 120 and the emission material layer 130 may be integrated, for example.

The encapsulation layer 140 may cover the emission material layer 130 and may be extended to the non-display area NA to contact the circuit layer 120. According to the embodiment of the disclosure, the encapsulation layer 140 may have, but is not limited to, a multi-layer structure including at least two inorganic encapsulation layers overlapping each other and at least one organic encapsulation film interposed between the inorganic encapsulation films.

According to the embodiment, the display panel 100 may be bent in the bending area BA. The bending area BA may be a part of the subsidiary area SBA and may be spaced apart from the main area MA.

The substrate 110 and the circuit layer 120 may be bent in the bending area BA corresponding to a portion of the subsidiary area SBA. Accordingly, the bezel area recognized by the user as the non-display area NA may be reduced or minimized.

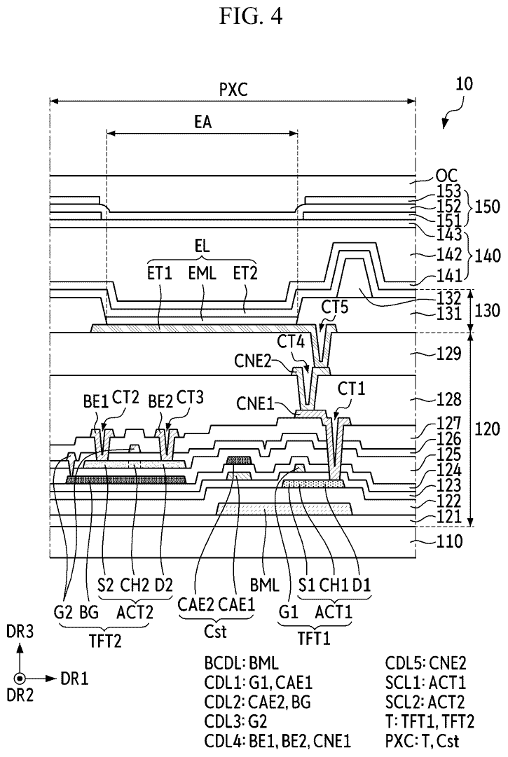

FIG. 4 is a cross-sectional view showing an embodiment of a sub-pixel of a display device according to the disclosure. FIG. 4 is a cross-sectional view showing a part of the display area DA that corresponds to a sub-pixel.

Referring to FIG. 4, the display panel 100 may include the substrate 110, the circuit layer 120 disposed on the substrate 110, the emission material layer 130, the encapsulation layer 140 and the color filter layer 150. The circuit layer 120, the emission material layer 130, the encapsulation layer 140 and the color filter layer 150 may be disposed or stacked sequentially on the substrate 110 in the third direction DR3.

The substrate 110 may include or consist of a flexible material that may be bent, folded, or rolled. The substrate 110 may include or consist of an insulating material such as a polymer resin. In an embodiment, the substrate 110 may include or consist of polyimide, for example.

The circuit layer 120 may include pixel circuits PXC and the lines. In an embodiment, the circuit layer 120 may include circuit elements (e.g., pixel transistors T and capacitors Cst) that form the pixel circuit PXC of each sub-pixel, and line electrically connected to the sub-pixels (e.g., a variety of power lines and signal lines including voltage lines, scan lines, emission control lines, and data lines), for example.

In the example shown in FIG. 4, among the elements that may be provided in the circuit layer 120, a first thin-film transistor TFT1 (also referred to as a first pixel transistor), a second thin-film transistor TFT2 (also referred to as a second pixel transistor), and a capacitor Cst included in the pixel circuit PXC of each sub-pixel are depicted. The first thin-film transistor TFT1 may represent first-type transistors (e.g., p-type oxide transistors) including a first semiconductor material (e.g., polysilicon) among the pixel transistors T forming the respective pixel circuits PXC. FIG. 4 shows, as the first thin-film transistor TFT1, one transistor that is connected to a light-emitting element EL through at least one connection electrode (e.g., a first connection electrode CNE1 and a second connection electrode CNE2) among the first-type transistors, for example. The second thin-film transistor TFT2 may represent second-type transistors (e.g., n-type transistors) including a second semiconductor material (e.g., oxide semiconductor) among the pixel transistors T.

The cross-section of the sub-pixels may vary depending on the type and/or structure of each of the sub-pixels and the display panel 100 including them. In an embodiment, the positions, formation order, etc., of the first thin-film transistor TFT1, the second thin-film transistor TFT2, the capacitor Cst, etc., may vary depending on embodiments, for example.

The circuit layer 120 may include semiconductor layers, conductive layers, and insulating films disposed between and/or around the conductive layers and the semiconductor layers for forming the circuit elements, the lines, etc. According to the embodiment of the disclosure, the circuit layer 120 may include: a first semiconductor layer SCL1 (e.g., a polysilicon semiconductor layer), a first insulating layer 123 (e.g., a first gate insulator), a first conductive layer CDL1 (e.g., a first gate conductive layer), a second insulating layer 124 (e.g., a second gate insulator), a second conductive layer CDL2 (e.g., a second conductive layer), a third insulating layer 125 (e.g., a first inter-dielectric layer), a second semiconductor layer SCL2 (e.g., an oxide semiconductor layer), a fourth insulating layer 126 (e.g., a third gate insulator), a third conductive layer CDL3 (e.g., a third gate conductive layer), a fifth insulating layer 127 (e.g., a second inter-dielectric layer), a fourth conductive layer CDL4 (e.g., a first source-drain conductive layer), and a sixth insulating layer 128 (e.g., a first via layer or a first planarization film), which are sequentially disposed on the substrate 110 in the third direction D3. According to the embodiment of the disclosure, the circuit layer 120 may further include a fifth conductive layer CDL5 (e.g., a second source-drain conductive layer) and a seventh insulating layer 129 (e.g., a second via layer or a second planarization layer) sequentially disposed on the sixth insulating layer 128. According to the embodiment of the disclosure, the circuit layer 120 may further include a bottom conductive layer BCDL disposed between the substrate 110 and the first semiconductor layer SCL1, a barrier layer 121 disposed between the substrate 110 and the bottom conductive layer BCDL, and a buffer layer 122 disposed between the bottom conductive layer BCDL and the first semiconductor layer SCL1.

The barrier layer 121 may be disposed on the substrate 110. The barrier layer 121 may protect elements disposed in the circuit layer 120 and the emission material layer 130 from moisture that permeates through the substrate 110, which is vulnerable to moisture permeation. The barrier layer 121 may include at least one inorganic film including an inorganic insulating material (e.g., silicon nitride, silicon oxide, silicon oxynitride, titanium oxide, aluminum oxide, or other inorganic insulating materials). The material of the barrier layer 121 may vary depending on embodiments.

The bottom conductive layer BCDL may be disposed on the barrier layer 121. The bottom conductive layer BCDL may include a bottom metal layer BML overlapping with an active layer (e.g., a first active layer ACT1 and/or a second active layer ACT2) of at least one pixel transistor T, and/or at least one line (or a part of the at least one line). Although the bottom metal layer BML is disposed to overlap with only the first active layer ACT1 of the first thin-film transistor TFT1 and capacitor electrodes CAE1 and CAE2 of the capacitor Cst in the example shown in FIG. 4, but the disclosure is not limited thereto. In an embodiment, the bottom metal layer BML may be patterned into an appropriate size and/or shape as desired and disposed on a portion of the pixel circuit PXC or on the front surface of the pixel circuit PXC, for example. According to the embodiment of the disclosure, the bottom metal layer BML may also be utilized as a light-blocking pattern and/or a back-gate electrode of at least one pixel transistor T.

The buffer layer 122 may be disposed over the bottom conductive layer BCDL and may cover the bottom conductive layer BCDL. The buffer layer 122 may include at least one inorganic film including or consisting of an inorganic insulating material.

The first thin-film transistor TFT1, the second thin-film transistor TFT2 and the capacitor Cst may be disposed on a surface of the substrate 110 including the buffer layer 122. The first thin-film transistor TFT1 may include a first active layer ACT1 and a first gate electrode G1. The second thin-film transistor TFT2 may include a second active layer ACT2 and a second gate electrode G2. According to the embodiment of the disclosure, the second thin-film transistor TFT2 may include a back-gate electrode BG. The capacitor Cst may include a first capacitor electrode CAE1 and a second capacitor electrode CAE2.

The first semiconductor layer SCL1 may be disposed on the buffer layer 122. The first semiconductor layer SCL1 may include a first active layer ACT1 of a first thin-film transistor TFT1.

The first active layer ACT1 may be provided in the first semiconductor layer SCL1 and may include a first semiconductor material (e.g., polysilicon). The first active layer ACT1 may include a first channel region CH1, a first source region S1 and a first drain region D1. The first channel region CH1 may overlap with the first gate electrode G1 in the third direction DR3. The first source region S1 may be disposed on one side of the first channel region CH1, and the first drain region D1 may be disposed on the opposite side of the first channel region CH1. The first source region S1 and the second drain region D1 may have conductivity by doping ions or impurities into a semiconductor for forming the first active layer ACT1. According to the embodiment, the first source region S1 may be a source electrode of the first thin-film transistor TFT1. In another embodiment, the first thin-film transistor TFT1 may include a separate source electrode connected to the first source region S1. According to the embodiment, the first drain region D1 may be a drain electrode of the first thin-film transistor TFT1. In another embodiment, the first thin-film transistor TFT1 may include a separate drain electrode connected to the first drain region D1.

The first insulating layer 123 may be disposed on the first semiconductor layer SCL1. The first insulating layer 123 may cover the first semiconductor layer SCL1.

The first conductive layer CDL1 may be disposed on the first insulating layer 123. The first conductive layer CDL1 may include the first gate electrode G1 of the first thin-film transistor TFT. The first gate electrode G1 may be disposed to overlap with a part of the first active layer ACT1 (e.g., the first channel region CH1). According to the embodiment of the disclosure, the first conductive layer CDL1 may further include at least one line (or a part of the at least one line), a metal pattern (e.g., a bridge pattern) and/or a capacitor electrode. In an embodiment, the first conductive layer CDL1 may further include a first capacitor electrode CAE1 of the capacitor Cst, for example.

According to the embodiment, the first capacitor electrode CAE1 may be formed integrally with the gate electrode of at least one first thin-film transistor TFT1. In an embodiment, the first capacitor electrode CAE1 and the gate electrode of the first thin-film transistor TFT1 may be formed as a single conductive pattern, and the second capacitor electrode CAE2 may be disposed to overlap with the conductive pattern, for example.

The second insulating layer 124 may be disposed on the first conductive layer CDL1. The second insulating layer 124 may cover the first conductive layer CDL1.

The second conductive layer CDL2 may be disposed on the second insulating layer 124. The second conductive layer CDL2 may include one electrode of the capacitor Cst, e.g., the second capacitor electrode CAE2. According to the embodiment, the second conductive layer CDL2 may further include at least one electrode, line (or a part of the at least one line), and/or a metal pattern (e.g., a bridge pattern). In an embodiment, the second conductive layer CDL2 may further include a back-gate electrode BG connected to the second gate electrode G2 of the second thin-film transistor TFT2, for example.

The third insulating layer 125 may be disposed on the second conductive layer CDL2. The third insulating layer 125 may cover the second conductive layer CDL2.

The second semiconductor layer SCL2 may be disposed on the third insulating layer 125. The second semiconductor layer SCL2 may include the second active layer ACT2 of the second thin-film transistor TFT2.

The second active layer ACT2 may be provided in the second semiconductor layer SCL2 and may include a second semiconductor material (e.g., an oxide semiconductor) different from the first semiconductor material. In an embodiment, the second active layer ACT2 may include indium (In)-gallium (Ga)-zinc (Zn)-oxygen (O) (“IGZO”), indium (In)-gallium (Ga)-zinc (Zn)-tin (Sn)-oxygen (O) (“IGZTO”) or indium (In)-gallium (Ga)-tin (Sn)-oxygen (O) (“IGTO”), for example.

The second active layer ACT2 may include a second channel region CH2, a second source region S2 and a second drain region D2. The second channel region CH2 may overlap with the second gate electrode G2 in the third direction DR3. The second source region S2 may be disposed on one side of the second channel region CH2, and the second drain region D2 may be disposed on an opposite side of the second channel region CH2. The second source region S2 and the second drain region D2 may have conductivity by doping ions or impurities into a semiconductor for forming the second active layer ACT2. According to the embodiment, the second source region S2 may be a source electrode of the second thin-film transistor TFT2. In another embodiment, the second thin-film transistor TFT2 may include a separate source electrode connected to the second source region S2. According to the embodiment, the second drain region D2 may be a drain electrode of the second thin-film transistor TFT2. In another embodiment, the second thin-film transistor TFT2 may include a separate drain electrode connected to the second drain region D2.

The fourth insulating layer 126 may be disposed on the second semiconductor layer SCL2. The fourth insulating layer 126 may cover the second semiconductor layer SCL2.

The third conductive layer CDL3 may be disposed on the fourth insulating layer 126. The third conductive layer CDL3 may include the second gate electrode G2 of the second thin-film transistor TFT2. The second gate electrode G2 may be disposed to overlap with a part of the second active layer ACT2 (e.g., the second channel region CH2). According to the embodiment of the disclosure, the third conductive layer CDL3 may further include at least one line (or a part of the at least one line), a metal pattern (e.g., a bridge pattern) and/or a capacitor electrode.

According to the embodiment of the disclosure, the electrodes, the conductive patterns and/or the lines provided in the bottom conductive layer BCDL, the first conductive layer CDL1, the second conductive layer CDL2 and the third conductive layer CDL3 may include a conductive material (e.g., at least one of molybdenum (Mo), aluminum (Al), chromium (Cr), gold (Au), titanium (Ti), nickel (Ni), neodymium (Nd), copper (Cu) and other metals, alloys thereof, or other conductive materials), and may have a single-layer or multi-layer structure. In an embodiment, each of the electrodes, the conductive patterns and/or lines provided in the bottom conductive layer BCDL, the first conductive layer CDL1, the second conductive layer CDL2 and the third conductive layer CDL3 may include molybdenum (Mo) or other metal materials, for example. At least two conductive layers among the bottom conductive layer BCDL, the first conductive layer CDL1, the second conductive layer CDL2 and the third conductive layer CDL3 may include the same material or different materials from each other. The material of each of the bottom conductive layer BCDL, the first conductive layer CDL1, the second conductive layer CDL2 and the third conductive layer CDL3 is not limited herein and may be variously changed depending on embodiments.

The fifth insulating layer 127 may be disposed on the third conductive layer CDL3. The fifth insulating layer 127 may cover the third conductive layer CDL3.

According to the embodiment of the disclosure, the first insulating layer 123, the second insulating layer 124, the third insulating layer 125, the fourth insulating layer 126 and the fifth insulating layer 127 may be inorganic insulating films including an inorganic insulating material (e.g., silicon nitride, silicon oxide, silicon oxynitride, titanium oxide, aluminum oxide, or other inorganic insulating materials). Each of them may have a single-layer or multi-layer structure. At least two insulating films among the first insulating layer 123, the second insulating layer 124, the third insulating layer 125, the fourth insulating layer 126 and the fifth insulating layer 127 may include the same material or different materials from each other. The material of each of the first insulating layer 123, the second insulating layer 124, the third insulating layer 125, the fourth insulating layer 126 and the fifth insulating layer 127 may vary depending on embodiments.

The fourth conductive layer CDL4 may be disposed on the fifth insulating layer 127. The fourth conductive layer CDL4 may include a first connection electrode CNE1 (or the drain electrode of the first thin-film transistor TFT1), a first bridge electrode BE1 (or the source electrode of the second thin-film transistor TFT2), and a second bridge electrode BE2 (or the drain electrode of the second thin-film transistor TFT2). The first connection electrode CNE1 may be provided in the fourth conductive layer CDL4, and may be connected to the first drain region D1 of the first active layer ACT1 through a first contact hole CT1 penetrating the first insulating layer 123, the second insulating layer 124, the third insulating layer 125, the fourth insulating layer 126 and the fifth insulating layer 127. The first bridge electrode BE1 may be provided in the fourth conductive layer CDL4 and may be connected to the second source region S2 of the second active layer ACT2 through a second contact hole CT2 penetrating the fourth insulating layer 126 and the fifth insulating layer 127. The second bridge electrode BE2 may be connected to the second drain region D2 of the second active layer ACT2 through a third contact hole CT3 penetrating the fourth insulating layer 126 and the fifth insulating layer 127. According to the embodiment, the fourth conductive layer CDL4 may further include at least one line (or a part of the at least one line), and/or a metal pattern (e.g., a bridge pattern). In an embodiment, the fourth conductive layer CDL4 may include parts of the power lines (e.g., a first pixel power line and/or a second pixel power line) provided inside and/or outside the display area DA, for example.

The sixth insulating layer 128 may be disposed on the fourth conductive layer CDL4. The sixth insulating layer 128 may cover the fourth conductive layer CDL4.

The fifth conductive layer CDL5 may be disposed on the sixth insulating layer 128. The fifth conductive layer CDL5 may include the second connection electrode CNE2. The second connection electrode CNE2 may be provided in the fifth conductive layer CDL5 and may be connected to the first connection electrode CNE1 through the fourth contact hole CT4 (or first via hole) penetrating the sixth insulating layer 128. According to the embodiment, the fifth conductive layer CDL5 may further include at least one line (or a part of the at least one line), and/or a metal pattern (e.g., a bridge pattern). In an embodiment, the fifth conductive layer CDL5 may include parts of the power lines (e.g., a first pixel power line and/or a second pixel power line) provided inside and/or outside the display area DA, for example.

According to the embodiment of the disclosure, the electrodes, the conductive patterns and/or the lines provided in the fourth conductive layer CDL4 and the fifth conductive layer CDL5 may include a conductive material (e.g., at least one of molybdenum (Mo), aluminum (Al), chromium (Cr), gold (Au), titanium (Ti), nickel (Ni), neodymium (Nd), copper (Cu) and other metals, alloys thereof, or other conductive materials), and may have a single-layer or multi-layer structure. In an embodiment, the electrodes, the conductive patterns, and/or the lines provided in the fourth conductive layer CDL4 and the fifth conductive layer CDL5 may be formed in a triple-layer structure of titanium/aluminum/titanium (Ti/Al/Ti), for example. The fourth conductive layer CDL4 and the fifth conductive layer CDL5 may include the same material or different materials from each other. The material of each of the fourth conductive layer CDL4 and the fifth conductive layer CDL5 may vary depending on embodiments.

The seventh insulating layer 129 may be disposed on the fifth conductive layer CDL5. The seventh insulating layer 129 may cover the fifth conductive layer CDL5.

According to the embodiment of the disclosure, each of the sixth insulating layer 128 and the seventh insulating layer 129 may be an organic insulating film including an organic insulating material (e.g., an acrylic resin, an epoxy resin, a phenolic resin, a polyamide resin, a polyimide resin, or other organic insulating materials) for planarization of the circuit layer 120, and may have a single-layer or multiple-layer structure. The sixth insulating layer 128 and the seventh insulating layer 129 may include the same material or different materials from each other. The material of each of the sixth insulating layer 128 and the seventh insulating layer 129 may vary depending on embodiments.

The emission material layer 130 may include a pixel-defining layer 131 that defines emission areas EA of the pixels, and the light-emitting elements EL disposed in the emission areas EA. According to the embodiment of the disclosure, the emission material layer 130 may further include a spacer 132 disposed on a portion of the pixel-defining layer 131.

Each of the light-emitting elements EL may include a first electrode ET1 (e.g., an anode electrode) connected to at least one transistor T (e.g., the first thin-film transistor TFT1) included in the respective sub-pixel through the first connection electrode CNE1 and/or the second connection electrode CNE2, and an emissive layer EML and a second electrode ET2 (e.g., a cathode electrode) sequentially disposed on the first electrode ET1. In an embodiment of the disclosure, each of the light-emitting elements EL may further include a first intermediate layer (e.g., a hole layer including a hole transport layer) interposed between the first electrode ET1 and the emissive layer EML, and a second intermediate layer (e.g., an electron transport layer including an electron transport layer) interposed between the emissive layer EML and the second electrode ET2.

The first electrode ET1 of each of the light-emitting element EL may include a conductive material and may be disposed on the circuit layer 120. In an embodiment, the first electrode ET1 may be disposed on the seventh insulating layer 129 in each of the emission areas EA, for example. The first electrode ET1 may be connected to the second connection electrode CNE2 through a fifth contact hole CT5 (or a second via hole) penetrating the seventh insulating layer 129.

In an embodiment of the disclosure, the first electrode ET1 may include a highly reflective metal material or a transparent conductive metal oxide. In an embodiment, the first electrode ET1 may have a single-layer structure of molybdenum (Mo), titanium (Ti), copper (Cu) or aluminum (Al), or may have a multi-layer structure including indium-tin-oxide (“ITO”), indium-zinc-oxide (“IZO”), zinc oxide (ZnO), indium oxide (In₂O₃) and silver (Ag), magnesium (Mg), aluminum (Al), platinum (Pt), lead (Pb), gold (Au) or nickel (Ni), etc. (e.g., ITO/Mg, ITO/MgF, ITO/Ag, ITO/Ag/ITO, etc.).

The emissive layer EML of the light-emitting element EL may include a relatively high molecular substance or a monomolecular substance. According to the embodiment of the disclosure, the emissive layer EML may be disposed in each of the sub-pixels, and the emissive layer EML of each of the sub-pixel may emit visible light of a color associated with the respective sub-pixel. In another embodiment, the emissive layer EML may be a common layer shared by the sub-pixels of different colors, and wavelength conversion layers and/or color filters corresponding to the colors (or wavelength bands) of lights to be emitted from the sub-pixels may be disposed in the emission areas EA of at least some of the sub-pixels.

The second electrode ET2 of each of the light-emitting elements EL may include a conductive material and may be connected to the second pixel voltage line. According to the embodiment of the disclosure, the second electrode ET2 may be a common layer formed over the entirety of the display area DA to cover the emissive layer EML and the pixel-defining layer 131. According to the embodiment of the disclosure, the second electrode ET2 may include or consist of a transparent conductive oxide (“TCO”) such as ITO and IZO that may transmit light, or a semi-transmissive conductive material such as magnesium (Mg), silver (Ag) and an alloy of magnesium (Mg) and silver (Ag). When the second electrode ET2 includes or consists of a semi-transmissive conductive material, the emission efficiency may be improved by a microcavity effect.

Optionally, a capping layer (not shown) may be disposed on the second electrode ET2. The capping layer may include an organic or inorganic insulating material to cover the light-emitting element EL. The capping layer may prevent the light-emitting element EL from being damaged by outside air. In an embodiment, the capping layer may include an organic material such as a-NPD, NPB, TPD, m-MTDATA, Alq₃, LiF and/or CuPc, or an inorganic material such as aluminum oxide, titanium oxide, tantalum oxide, hafnium oxide, zinc oxide, silicon oxide, silicon nitride, and/or silicon oxynitride.

The pixel-defining layer 131 may define openings associated with the emission areas EA and may surround the emission areas EA. In an embodiment, the pixel-defining layer 131 may be formed to cover an edge of the first electrode ET1 of the light-emitting element EL, and may define an opening that exposes the remaining portion of the first electrode ET1, for example. The area where the exposed first electrode ET1 and the emissive layer EML overlap each other (or an area including the same) may be defined as the emission area EA of each pixel PX.

In an embodiment of the disclosure, the pixel-defining layer 131 may include at least one organic film including or consisting of an organic insulating material. In an embodiment, the pixel-defining layer 131 may include a polyacrylate resin, an epoxy resin, a phenolic resin, a polyamide resin, a polyimide resin, an unsaturated polyester resin, a polyphenylene resin, a polyphenylene sulfide resin, benzocyclobutene (“BCB”), or other organic insulating materials, for example.

Although not shown in the drawings, the spacer may be disposed on a part of the pixel-defining layer 131. The spacer may include at least one organic film including or consisting of an organic insulating material. In an embodiment of the disclosure, the spacer may include the same material as that of the pixel-defining layer 131 or may include a different material from the pixel-defining layer 131. The organic insulating material forming the spacer is not particularly limited herein, and may vary depending on embodiments.

The encapsulation layer 140 may be disposed on the emission material layer 130. The encapsulation layer 140 may block the permeation of oxygen or moisture into the emission material layer 130 and may alleviate electrical or physical shock on the circuit layer 120 and the emission material layer 130.

The encapsulation layer 140 may include a first encapsulation layer 141, a second encapsulation layer 142, and a third encapsulation layer 143 sequentially disposed on the emission material layer 130. The first encapsulation layer 141 and the third encapsulation layer 143 may include an inorganic insulating material, and the second encapsulation layer 142 may include an organic material.

The inorganic insulating material included in the first encapsulation layer 141 and the third encapsulation layer 143 may include, but is not limited to, aluminum oxide, titanium oxide, tantalum oxide, hafnium oxide, zinc oxide, silicon oxide, silicon nitride, and/or silicon oxynitride, which may be produced using physical vapor deposition (“PVD”), chemical vapor deposition (“CVD”), or atomic layer deposition (“ALD”).

The organic material included in the second encapsulation layer 142 may include, but is not limited to, an acrylic-based polymer, a silicon-based polymer and an epoxy-based polymer that may block moisture and oxygen. Preferably, it may be, but is not limited to, polyamide, polyimide, polycarbonate, polypropylene (“PP”), polyacrylic acid (“PAA”), polyacrylate, urethane acrylate, polyester, polyethylene (“PE”), polystyrene (“PS”), polysiloxane, polysilazane, and epoxy-based resin.

The first encapsulation layer 141, the second encapsulation layer 142 and the third encapsulation layer 143 will be described in detail later.

The display device 10 may include the color filter layer 150 disposed on the encapsulation layer 140. The color filter layer 150 may include first color filters 151, second color filters 152 and third color filters 153. Each of the first color filters 151, the second color filters 152 and the third color filters 153 may include a filtering pattern region and a light-blocking region. The filtering pattern region may be formed to overlap with the emission area EA, and may form a light-exit area from which light emitted from the emission area EA exits. In the light-blocking region, the color filters CF1, CF2 and CF3 are stacked on one another in the third direction DR3, and light cannot pass through it.

The first color filters 151, the second color filters 152 and the third color filters 153 may include a first color filter 151, a second color filter 152 and a third color filter 153 disposed in different emission areas EA, respectively. Each of the first color filters 151, the second color filters 152 and the third color filters 153 may include a colorant such as a dye and pigment that absorbs lights in wavelength ranges other than light in a particular wavelength range, and may be disposed in association with the color of the light exiting from the emission areas EA. In an embodiment, the first color filter 151 may be a red color filter that transmits only a first red light, for example. The second color filter 152 may be a green color filter that transmits only a second green light, and the third color filter 153 may be a blue color filter that transmits only a third blue light. Although only the filtering pattern region of the second color filter 152 overlaps with the emission area EA in the example shown in FIG. 4, the emission area of another neighboring (adjacent) sub-pixel may overlap with the filtering pattern region of the first color filter 151 or the filtering pattern region of the third color filter 153.

The display device 10 may reduce the intensity of reflected light due to external light as the first color filter 151, the second color filter 152 and the third color filter 153 overlap each other. Furthermore, the color gamut of reflected light due to external light may be controlled by adjusting the arrangement, shape, area, etc., of the first color filter 151, the second color filter 152 and the third color filter 153 when viewed from the top.

An overcoat layer OC may be disposed on the color filter layer 150 to provide a flat surface over the steps created by the first color filter 151, the second color filter 152 and the third color filter 153. The overcoat layer OC may be a colorless light-transmitting layer having no color in the visible light range. In an embodiment, the overcoat layer OC may include a colorless light-transmitting organic material such as an acryl-based resin, for example.

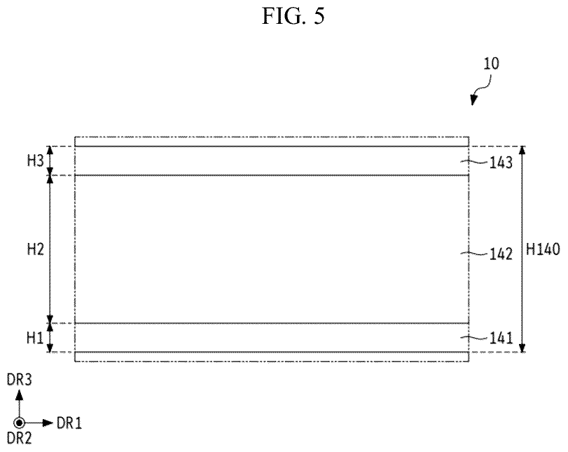

FIG. 5 is a cross-sectional view showing an embodiment of an encapsulation layer of a display device according to the disclosure.

Referring to FIG. 5, the first encapsulation layer 141 in the embodiment may have a relatively small thickness. Specifically, a thickness H1 of the first encapsulation layer 141 may be smaller than a thickness H2 of the second encapsulation layer 142. In an embodiment, the thickness H1 of the first encapsulation layer 141 may range from 10 angstroms to 100 angstroms, for example, but the disclosure is not limited thereto. With the thickness H1 within the above range, the first encapsulation layer 141 may be formed at a high density within a short process time.

In addition, the first encapsulation layer 141 may have a relatively high density film. Specifically, the film density of the first encapsulation layer 141 may be equal to or greater than 2.1 grams per cubic centimeter (g/cm³), and the water vapor transmission rate (“WVTR”) may be equal to or less than 1×10⁻⁴ gram per square meter per day (g/m²day) or less.

Herein, the WVTR is a numerical value that represents the amount of moisture passing through a predetermined film or layer per unit time per unit area, and may be measured according to ASTM F1249 standard. WVTR may be measured using AQUATRAN2 or AQUATRAN3 testing system (commercially available from MOCON, Inc, Minneapolis, Minn.).

In addition, the first encapsulation layer 141 may have a refractive index in a range that may increase the emission efficiency of light output from the emission material layer 130. Specifically, the refractive index of the first encapsulation layer 141 may be equal to or greater than 1.85. The refractive indices may be measured using an optical measuring instrument such as an ellipsometer and a spectral reflectometer. The ellipsometer may measure the refractive index by measuring the amounts of polarization changes of the incident light and the reflected light with respect to an inorganic film to calculate the thickness and complex refractive index of the inorganic film. The spectral reflectometer may measure the refractive index of an inorganic film by comparing the intensities of lights obtained by varying the wavelength. The refractive index may be a value measured at room temperature and normal pressure.

In other words, the first encapsulation layer 141 may have the small thickness H1 described above, excellent barrier properties, and a refractive index of 1.85 or more to increase the light efficiency.

According to the embodiment of the disclosure, the second encapsulation layer 142 may be disposed on the first encapsulation layer 141. The second encapsulation layer 142 may include an organic material, and for example, may include polysilazane. The term polysilazane may be used interchangeably with terms silazane, and organic polysilazane, for example.

The thickness H2 of the second encapsulation layer 142 may be larger than the thickness H1 of the first encapsulation layer 141 and the thickness H3 of the third encapsulation layer 143. In an embodiment, the thickness H2 of the second encapsulation layer 142 may range from 1,000 angstroms to 4,000 angstroms, but the disclosure is not limited thereto.

In addition, the second encapsulation layer 142 may have relatively high barrier properties compared to typical organic materials (e.g., silicone resin, epoxy resin, acrylic resin, and silicone acrylic resin). Specifically, the WVTR of the second encapsulation layer 142 may be equal to or less than 1×10⁻³ g/m²day.

In addition, the second encapsulation layer 142 may have relatively high refractive index compared to typical organic materials (e.g., silicone resin, epoxy resin, acrylic resin, and silicone acrylic resin). In an embodiment, the refractive index of the second encapsulation layer 142 may be equal to or greater than 1.80, for example. The range of the refractive index may be determined to maximize the emission efficiency of light output from the emission material layer 130.

In other words, the second encapsulation layer 142 may include an organic material, may have excellent barrier properties, and may have a refractive index of 1.80 or more that increases the light efficiency properties.

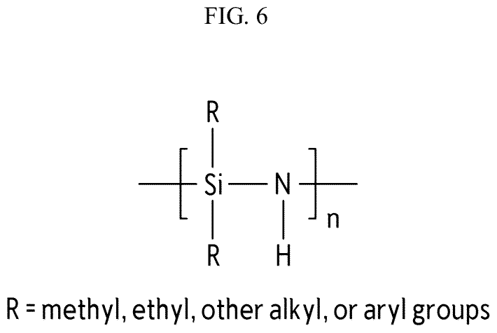

Referring to FIG. 6, polysilazane included in the second encapsulation layer 142 may be characterized by including silicon-nitrogen (Si—N) bonds as repetition units and nitrogen-hydrogen (N—H) bonds and functional groups (R) connected to opposite sides of silicon (Si). The above functional groups R may include methyl, ethyl, alkyl compounds, and/or aryl compounds. In other words, the second encapsulation layer 142 may include polysilazane including a number of Si-N bonds, N—H bonds, and Si—C (Si—R) bonds.

According to the embodiment of the disclosure, the third encapsulation layer 143 may be disposed on the second encapsulation layer 142. The structure and characteristics of the third encapsulation layer 143 may be similar to the structure and characteristics of the first encapsulation layer 141.

Specifically, the thickness H3 of the third encapsulation layer 143 may be smaller than the thickness H2 of the second encapsulation layer 142. In an embodiment, the thickness H3 of the third encapsulation layer 143 may range from 10 angstroms to 100 angstroms, for example, but the disclosure is not limited thereto. With the thickness H3 within the above range, the third encapsulation layer 143 may be formed at a relatively high density within a short process time.

In addition, the film density of the third encapsulation layer 143 may be equal to or greater than 2.1 g/cm³, and the WVTR may be equal to or less than 1×10⁻⁴ g/m²day.

In addition, the refractive index of the third encapsulation layer 143 may be equal to or greater than 1.85. The range of the refractive index may be determined to maximize the emission efficiency of light output from the emission material layer 130.

In other words, the third encapsulation layer 143 may have the relatively small thickness H3 described above, excellent barrier properties, and a refractive index of 1.85 or more to increase the light efficiency.

The encapsulation layer 140 in the embodiment includes the first encapsulation layer 141, the second encapsulation layer 142 and the third encapsulation layer 143 that have a relatively small thickness and relatively high barrier properties, and thus may have relatively high barrier properties even though the total thickness H140 of the encapsulation layer 140 is equal to or less than 10,000 angstroms.

In the process of fabricating the display device 10, the first encapsulation layer 141 and the third encapsulation layer 143 may be formed by plasma-enhanced atomic layer deposition (“PEALD”), and the second encapsulation layer 142 may be formed by any equipment that may apply organic materials. Such a fabrication process will be described later.

Hereinafter, a method of fabricating the encapsulation layer 140 will be described with reference to other drawings.

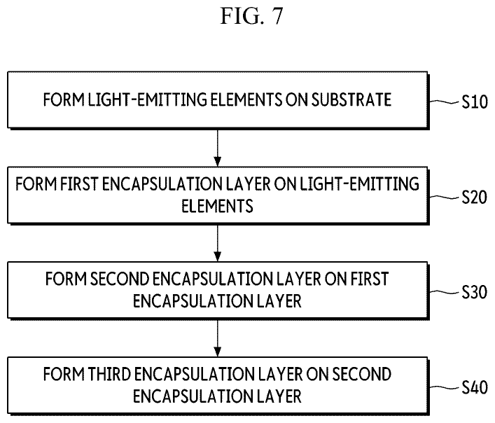

FIG. 7 is a flowchart for illustrating an embodiment of a method of fabricating a display device according to the disclosure.

Referring to FIG. 7, a method of fabricating a display device 10 in an embodiment may include: forming a plurality of light-emitting elements EL on a substrate (operation S10); forming a first encapsulation layer 141 on the light-emitting elements EL (operation S20); forming a second encapsulation layer 142 on the first encapsulation layer 141 (operation S30); and forming a third encapsulation layer 143 on the second encapsulation layer 142 (operation S40).

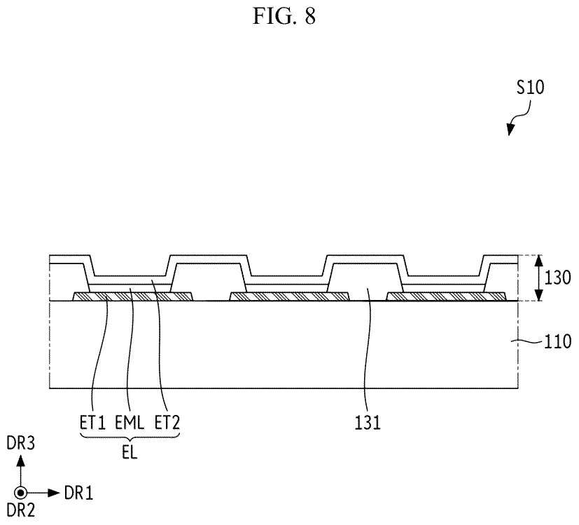

FIG. 8 is a cross-sectional view showing operation S10 of FIG. 7.

Referring to FIG. 8, operation S10 of forming a plurality of light-emitting elements EL on a substrate 110 is performed to form an emission material layer 130. A pixel-defining layer 131 may be formed on the substrate 110, and the plurality of light-emitting elements EL may be formed in openings of the pixel-defining layer 131. The structures of the pixel-defining layer 131 and the light-emitting elements EL are identical to those described above. Each of these processes may be conducted as a patterning process, a deposition process or the like well known in the art.

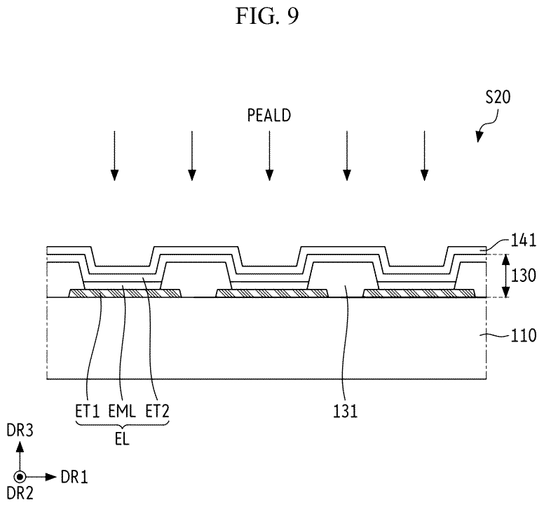

FIG. 9 is a cross-sectional view showing operation S20 of FIG. 7.

Referring to FIG. 9, operation S20 of forming a first encapsulation layer 141 over the light-emitting elements EL is performed. In this process, the first encapsulation layer 141 may be formed by PEALD. Therefore, the deposition temperature of this process may be relatively low, and the film density of the first encapsulation layer 141 may be high.

In this process, the process of forming the first encapsulation layer 141 may use aminosilane precursor. The aminosilane precursor may have silicon-nitrogen (Si—N) bond as a core structure, and may include, but is not limited to, at least one of: cyclosilazane, trisilylamine, bis(diethylamino)silane (BDEAS), bis(t-butylamino)silane (BTBAS), tris(dimethylamino)silane, tris(isopropylamino)silane, tetrakis(dimethylamino)silane, tri(isopropyl)cyclotrisilazane, and tetramethyldisilazane.

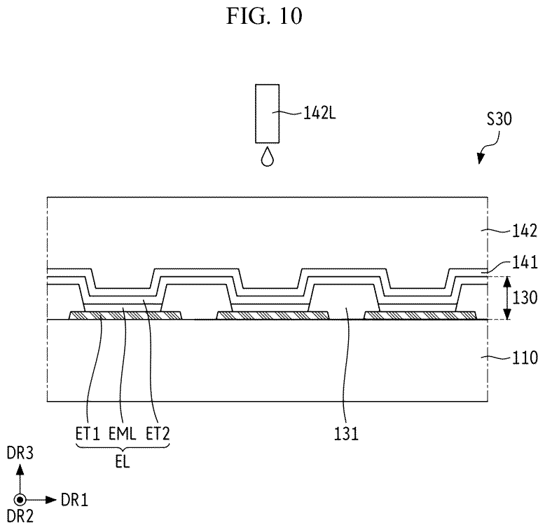

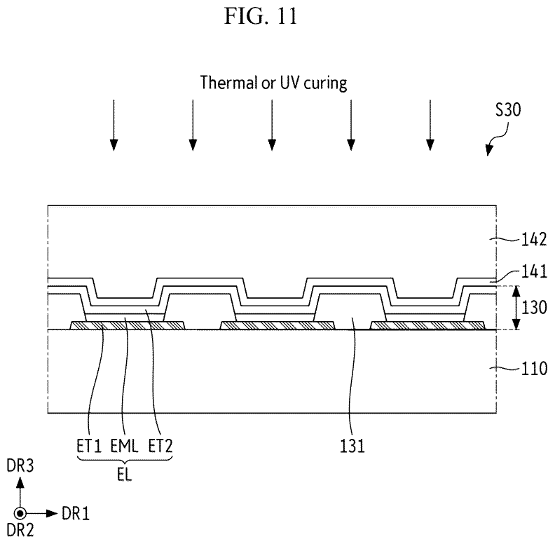

FIGS. 10 to 11 are cross-sectional views showing operation S30 of FIG. 7.

Referring to FIGS. 10 and 11, operation S30 of forming the second encapsulation layer 142 on the first encapsulation layer 141 is performed. In this process, a material 142L for forming the second encapsulation layer 142 may have a viscosity of 50 centipoise (cps) or less.

The process of forming the second encapsulation layer 142 may not be limited to particular process equipment as long as an organic material of 50 cps or less may be applied, such as spin coating, slit coating, jet dispensing, and inkjet printing. In other words, the second encapsulation layer 142 may be applied to various application facilities without limitation on the size of display devices, and may be easily produced in the fabrication process.

Subsequently, the applied second encapsulation layer 142 is cured. This process may be performed by thermal curing or ultraviolet (“UV”) curing depending on an initiator included in the second encapsulation layer 142.

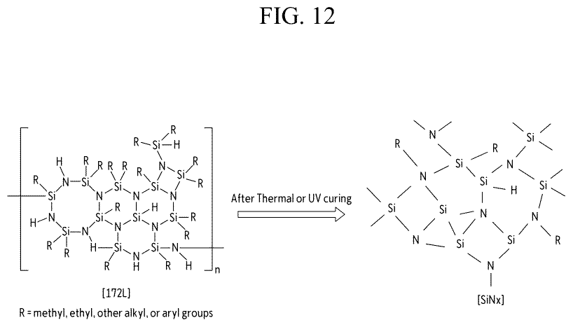

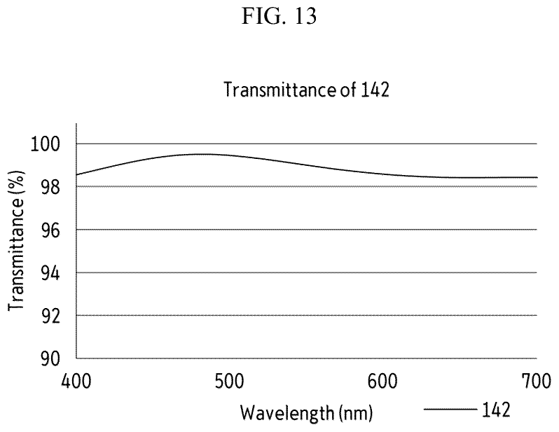

FIG. 12 shows chemical formulas of the organic material included in the second encapsulation layer before and after curing. FIG. 13 shows a graph of the transmittance of the second encapsulation layer.

Referring to FIGS. 12 and 13, the material 142L forming the second encapsulation layer 142 may include polysilazane including Si—N bonds, N—H bonds, and Si—C (Si—R) bonds. In this process, the material 142L forming the second encapsulation layer 142 undergoes a subsequent curing process, such that a number of functional groups R and hydrogen (H) may be separated. As a result, the second encapsulation layer 142 after the curing process may include silicon nitride (SiNx) including or consisting of a relatively large number of Si—N bonds and a relatively small amount of N—R bonds (N—C bonds). Although not shown in the drawing, a portion of the polysilazane that has not reacted through this process may remain in the second encapsulation layer 142.

The transmittance of the second encapsulation layer 142 after the curing process has been completed may be equal to or greater than 98%. Such a transmittance may mean that the second encapsulation layer 142 may transmit light output from the emission material layer 130 without loss.

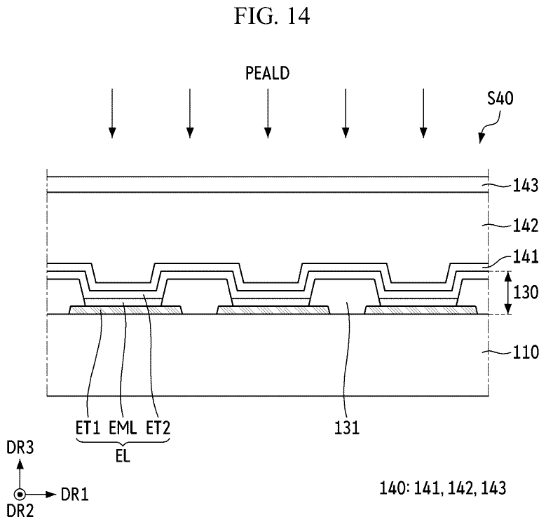

FIG. 14 is a cross-sectional view showing operation S40 of FIG. 7.

Referring to FIG. 14, operation S40 of forming the third encapsulation layer 143 on the second encapsulation layer 142 is performed. The forming the third encapsulation layer 143 may be identical to operation S10 of forming the first encapsulation layer 141 shown in FIG. 9. That is to say, the process of forming the third encapsulation layer 143 may be formed by PEALD, and may use aminosilane precursor. The redundant descriptions will be omitted.

In this manner, the substrate 110, the emission material layer 130 and the encapsulation layer 140 may be formed.

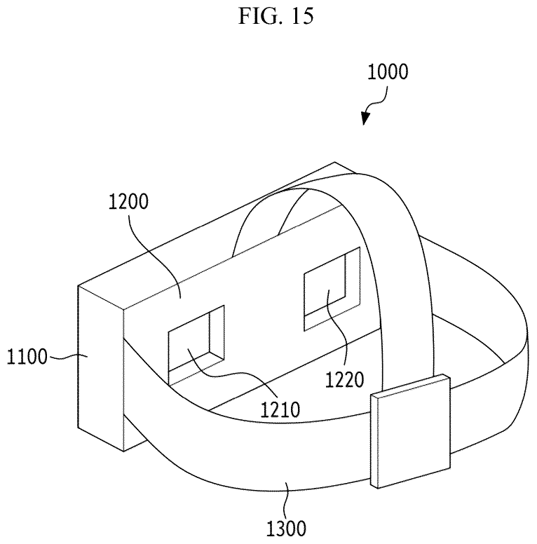

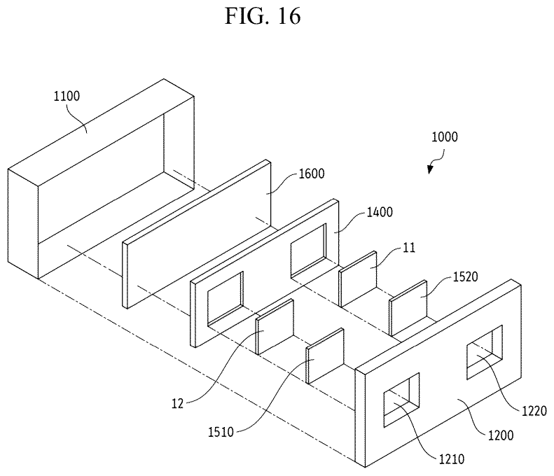

FIG. 15 is a perspective view showing an embodiment of a head-mounted display according to the disclosure. FIG. 16 is an exploded perspective view of an embodiment of the head-mounted display of FIG. 15.

Referring to FIGS. 15 and 16, an electronic device (e.g., a head-mounted display device 1000) in an embodiment includes a first display device 11, a second display device 12, a display device housing 1100, a housing cover 1200, a first eyepiece 1210, a second eyepiece 1220, a head strap band 1300, a middle frame 1400, a first optical member 1510, a second optical member 1520, a control circuit board 1600, and a connector. However, the disclosure is not limited thereto, and the display devices may be included in various other electronic devices.

A first display device 11 provides images to the user's left eye, and a second display device 12 provides images to the user's right eye. The first display device 11 and the second display device 12 are substantially identical to the display device 10 described above with reference to FIG. 1; and, therefore, the redundant description will be omitted.

The first optical member 1510 may be disposed between the first display device 11 and the first eyepiece 1210. The second optical member 1520 may be disposed between the second display device 12 and the second eyepiece 1220. Each of the first optical member 1510 and the second optical member 1520 may include at least one convex lens.

The middle frame 1400 may be disposed between the first display device 11 and the control circuit board 1600, and may be disposed between the second display device 12 and the control circuit board 1600. The middle frame 1400 serves to support and fix the first display device 11, the second display device 12 and the control circuit board 1600.

The control circuit board 1600 may be disposed between the middle frame 1400 and the display device housing 1100. The control circuit board 1600 may be connected to the first display device 11 and the second display device 12 through the connector. The control circuit board 1600 may convert an image source input from the outside into digital video data and may transmit the digital video data to the first display device 11 and the second display device 12 through the connector.

The control circuit board 1600 may transmit digital video data associated with a left-eye image optimized for the user's left eye to the first display device 11, and may transmit digital video data DATA associated with a right-eye image optimized for the user's right eye to the second display device 12. In an alternative embodiment, the control circuit board 1600 may transmit the same digital video data to the first display device 11 and the second display device 12.

The display device housing 1100 accommodates the first display device 11, the second display device 12, the middle frame 1400, the first optical member 1510, the second optical member 1520, the control circuit board 1600, and the connector. The housing cover 1200 is disposed to cover the open face of the display device housing (also referred to as a housing) 1100. The housing cover 1200 may include the first eyepiece 1210 where the user's left eye is placed, and the second eyepiece 1220 where the user's right eye is placed. Although the first eyepiece 1210 and the second eyepiece 1220 are separately disposed in the example shown in FIGS. 15 and 16, the embodiments of the disclosure are not limited thereto. The first eyepiece 1210 and the second eyepiece 1220 may be combined into a single element.

The first eyepiece 1210 may be aligned with the first display device 11 and the first optical member 1510, and the second eyepiece 1220 may be aligned with the second display device 12 and the second optical member 1520. Therefore, a user may see virtual images of images on the first display device 11 magnified by the first optical member 1510 through the first eyepiece 1210, and virtual images of images on the second display device 12 magnified by the second optical member 1520 through the second eyepiece 1220.

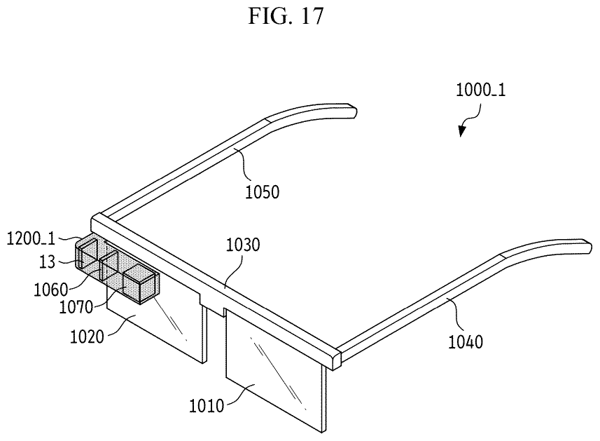

The head strap band 1300 fixes the housing 1100 to the user's head so that the first eyepiece 1210 and the second eyepiece 1220 of the housing cover 1200 remain in line with the user's left and right eyes, respectively. In another embodiment, by implementing a display device housing (e.g., 1200_1 of FIG. 17) which is relatively light and small, the head-mounted display device (e.g., 1000_1 of FIG. 17) may include an eyeglasses frame instead of a head strap band as shown in FIG. 15.

In addition, the head-mounted display device 1000 may further include a battery for supplying power, an external memory slot for inserting an external memory, and an external connection port and a wireless communication module for receiving an image source. The external connection port may be a universe serial bus (“USB”) terminal, a display port, or a high-definition multimedia interface (“HDMI”) terminal. The wireless communication module may be a 5G communication module, a 4G communication module, a Wi-Fi module, or a Bluetooth® module.

FIG. 17 is a perspective view showing an embodiment of a head-mounted display according to the disclosure.

Referring to FIG. 17, the head-mounted display device 1000_1 in the embodiment may be a glasses-type display device with a display device housing 1200_1 which is relatively light and small. The head-mounted display device 1000_1 in the embodiment may include a display device 13, a left-eye lens 1010, a right-eye lens 1020, a support frame 1030, eyeglass temples 1040 and 1050, an optical member 1060, an optical path conversion members 1070, and a display device housing 1200_1.

The display device housing 1200_1 may include the display device 13, the optical member 1060, and the optical path conversion member 1070. The images displayed on the display device 13 may be magnified by the optical member 1060, and the optical path of the images may be converted by the optical path conversion member 1070 to be provided to the user's right eye through the right-eye lens 1020. As a result, the user may see, with the right eye, augmented reality images that combine virtual images displayed on the display device 13 with real world images viewed through the right-eye lens 1020.

Although the display device housing 1200_1 is disposed at the right end of the support frame 1030 in the example shown in FIG. 17, the embodiments of the disclosure are not limited thereto. In an embodiment, the display device housing 1200_1 may be disposed at the left end of the support frame 1030, for example. In such case, images displayed on the display device 13 may be provided to the user's left eye. In an alternative embodiment, the display device housing 1200_1 may be disposed at both the left and right ends of the support frame 1030, respectively. In such case, the user may watch images displayed on the display device 13 through both the left and right eyes.

The display device according to one embodiment of the present disclosure can be applied to various electronic devices. The electronic device according to the one embodiment of the present disclosure includes the display device described above, and may further include modules or devices having additional functions in addition to the display device.

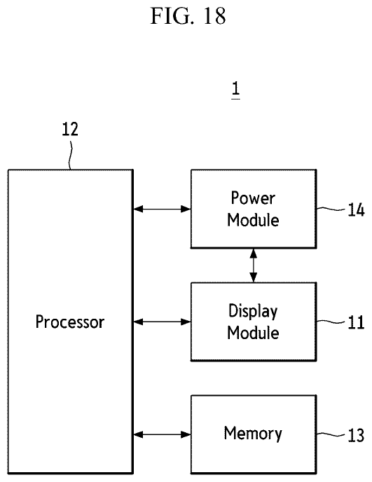

FIG. 18 is a block diagram of an electronic device according to one embodiment of the present disclosure.

Referring to FIG. 18, the electronic device 1 according to one embodiment of the present disclosure may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information necessary for the operation of the processor 12 or the display module 11. When the processor 12 executes an application stored in the memory 13, an image data signal and/or an input control signal is transmitted to the display module 11, and the display module 11 can process the received signal and output image information through a display screen.

The power module 14 may include a power supply module such as, for example a power adapter or a battery, and a power conversion module that converts the power supplied by the power supply module to generate power necessary for the operation of the electronic device 1.

At least one of the components of the electronic device 11 according to the one embodiment of the present disclosure may be included in the display device 10 according to the embodiments of the present disclosure. In addition, some modules of the individual modules functionally included in one module may be included in the display device 10, and other modules may be provided separately from the display device 10. For example, the display device 10 may include the display module 11, and the processor 12, the memory 13, and the power module 14 may be provided in the form of other devices within the electronic device 11 other than the display device 10.

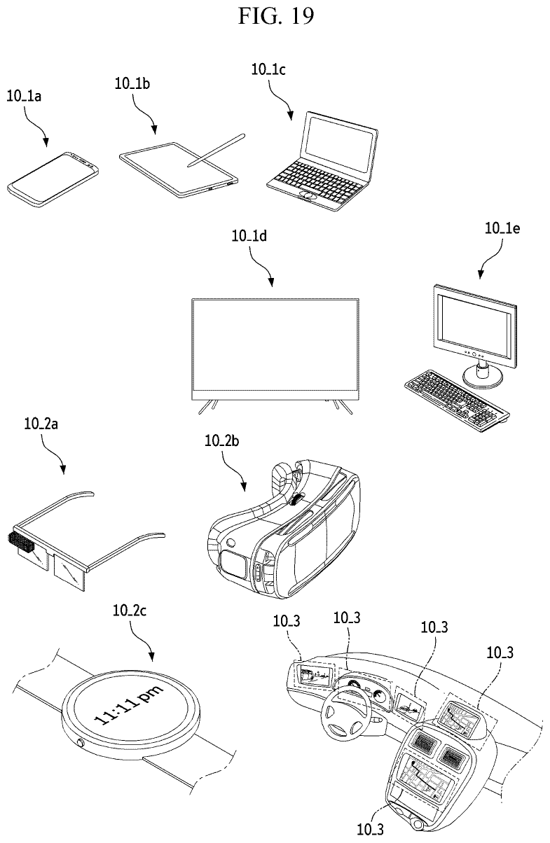

FIG. 19 is a schematic diagram of an electronic device according to various embodiments of the present disclosure.

Referring to FIG. 19, various electronic devices to which display devices 10 according to embodiments of the present disclosure are applied may include not only image display electronic devices such as a smart phone 10_1a, a tablet PC (personal computer) 10_1b, a laptop 10_1c, a TV 10_1d, and a desk monitor 10_1e, but also wearable electronic devices including display modules such as, for example smart glasses 10_2a, a head mounted display 10_2b, and a smart watch 10_2c, and vehicle electronic devices 10_3 including display modules such as a CID (Center Information Display) and a room mirror display arranged on a dashboard, center fascia, and dashboard of an automobile.

The embodiments of the disclosure have been described hereinabove with reference to the accompanying drawings, but it will be understood by one of ordinary skill in the art to which the disclosure pertains that various modifications and alterations may be made without departing from the technical spirit or essential feature of the disclosure. Therefore, it is to be understood that the embodiments described above are illustrative rather than being restrictive in all features.

Embodiments of the disclosure should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
an emission material layer disposed on a substrate and comprising a plurality of light-emitting elements; and
an encapsulation layer comprising:
a first encapsulation layer disposed on the emission material layer and including an inorganic material;
a second encapsulation layer disposed on the first encapsulation layer and including an organic material; and
a third encapsulation layer disposed on the second encapsulation layer and including the inorganic material,
wherein a total thickness of the encapsulation layer is equal to or less than 10,000 angstroms, and
wherein a refractive index of the second encapsulation layer is equal to or greater than 1.80.

2. The display device of claim 1, wherein the second encapsulation layer comprises silazane.

3. The display device of claim 2, wherein a water vapor transmission rate of the second encapsulation layer is equal to or less than 1×10⁻³ gram per square meter per day.

4. The display device of claim 3, wherein a transmittance of the second encapsulation layer in a visible range is equal to or greater than 98%.

5. The display device of claim 4, wherein a thickness of the second encapsulation layer ranges from 1,000 angstroms to 4,000 angstroms.

6. The display device of claim 1, wherein a difference between a refractive index of the first encapsulation layer and the refractive index of the second encapsulation layer and a difference between a refractive index of the third encapsulation layer and the refractive index of the second encapsulation layer are equal to or less than 0.1.

7. The display device of claim 6, wherein the refractive index of the first encapsulation layer and the refractive index of the third encapsulation layer are greater than the refractive index of the second encapsulation layer.

8. The display device of claim 7, wherein the refractive index of the first encapsulation layer and the refractive index of the third encapsulation layer are equal to or greater than 1.85.

9. The display device of claim 1, wherein the first encapsulation layer covers an entirety of the emission material layer, the second encapsulation layer covers an entirety of the first encapsulation layer, and the third encapsulation layer covers an entirety of the second encapsulation layer.

10. The display device of claim 1, wherein a film density of the first encapsulation layer and a film density of the third encapsulation layer are equal to or greater than 2.1 g/cm³.

11. The display device of claim 10, wherein each of a thickness of the first encapsulation layer and a thickness of the third encapsulation layer ranges from 10 angstroms to 100 angstroms.

12. The display device of claim 11, wherein a water vapor transmission rate of the first encapsulation layer and the third encapsulation layer are equal to or less than 1×10⁻⁴ gram per square meter per day.

13. The display device of claim 1, further comprising:
a circuit layer disposed between the substrate and the emission material layer,
wherein the circuit layer comprises a first semiconductor layer, a first insulating layer, a first conductive layer, a second insulating layer, a second conductive layer, a third insulating layer, a second semiconductor layer, a fourth insulating layer, a third conductive layer, a fifth insulating layer and a fourth conductive layer sequentially disposed on the substrate.

14. A method of fabricating a display device, the method comprising:
forming an emission material layer comprising a plurality of light-emitting elements on a substrate; and
forming an encapsulation layer on the emission material layer, the forming the encapsulation layer comprising:
forming a first encapsulation layer;
forming a second encapsulation layer on the first encapsulation layer; and
forming a third encapsulation layer on the second encapsulation layer, and
wherein a total thickness of the encapsulation layer is equal to or less than 10,000 angstroms, and the second encapsulation layer comprises silazane.

15. The method of claim 14, wherein the second encapsulation layer has a viscosity of 50 centipoise or less.

16. The method of claim 15, wherein the forming the second encapsulation layer comprises: forming the second encapsulation layer using at least one of: inkjet printing, jet dispensing, spin coating, slit coating, and screen printing.

17. The method of claim 16, wherein the forming the second encapsulation layer comprises: forming the second encapsulation layer by performing thermal curing or ultraviolet curing, and
wherein the second encapsulation layer comprises silicon nitride after the thermal curing or the ultraviolet curing.

18. The method of claim 14, wherein the forming the first encapsulation layer and the third encapsulation layer comprises: forming the first encapsulation layer and the third encapsulation layer by plasma-enhanced atomic layer deposition.

19. The method of claim 18, wherein the forming the first encapsulation layer and the third encapsulation layer comprises: forming the first encapsulation layer and the third encapsulation layer by aminosilane precursor.

20. An electronic device comprising:
a display device comprising a substrate;
a display device housing in which the display device is accommodated, the display device comprising:
an emission material layer disposed on the substrate and comprising a plurality of light-emitting elements; and
an encapsulation layer comprising:
a first encapsulation layer disposed on the emission material layer and including an inorganic material;
a second encapsulation layer disposed on the first encapsulation layer and including an organic material; and
a third encapsulation layer disposed on the second encapsulation layer and including an inorganic material; and
an optical member for magnifying a displayed image of the display device or converting a light path,
wherein a refractive index of the second encapsulation layer is equal to or greater than 1.8, and
wherein a water vapor transmission rate of the second encapsulation layer is equal to or less than 1×10⁻³ gram per square meter per day.
